(19) United States
(12) Patent Application Publication
(10) Pub. No.: US 2005/0105637 A1
(43) Pub. Date: May 19, 2005

(54) Bi-phase modulator for ultra wideband signals

(76) Inventors: Douglas Don Fitzpatrick, Madison, AL (US); Dennis L. Troutman, Huntsville, AL (US); David M. Dickson, Cedar Park, TX (US)

Correspondence Address: VENABLE, BAETJER, HOWARD AND CIVILETTI, LLP, P.O. BOX 34385, WASHINGTON, DC, 20043-9998, US

(21) Appl. No.: 10/712,271

(22) Filed: Nov. 14, 2003

(51) Int. Cl. H03K 7/04

(52) U.S. Cl. 375/295

(57) ABSTRACT

A bi-phase modulator for Ultra Wideband (UWB) waveforms uses a symmetrical transformation device and a selector device to produce bi-phase modulated UWB waveforms in response to an information signal. The symmetrical transformation device receives an input UWB waveform and produces equal but opposite polarity output waveforms. The selector device determines whether an inverted or non-inverted UWB waveform is output in response to the information signal.

### FIELD OF THE INVENTION

This invention relates to the fields of communication and radar systems and more particularly to bi-phase modulation of Ultra Wideband (UWB) signals.

### BACKGROUND OF THE INVENTION

UWB technology holds great promise for a vast array of new applications that provide significant benefits for public safety, business, and consumers. These applications include, but are not limited to, the concurrent conveyance of voice, video, data, position information, and mono/bi-static radar detection.

The FCC presently defines UWB as “An intentional radiator that, at any point in time, has a fractional bandwidth equal to or greater than 0.20 or has a UWB bandwidth equal to or greater than 500 MHz, regardless of the fractional bandwidth.”[Section 15.503] UWB technology is often referred to as “impulse radio” but may employ any of several types of transmitted waveforms. These bandwidths are often achieved by creating a short several-cycle waveform (a.k.a. pulse or wavelet) tailored to result in a spectral occupancy meeting some mask. Other systems employ a swept radio frequency (RF) carrier or sub-band schemes that similarly meet the definition of UWB.

Modulation, for the purposes of this application, is the process of encoding information on a UWB transmission. One known technique is Pulse Position Modulation (PPM). PPM requires precisely positioning pulses in time based on an information signal. Other techniques can utilize any combination of time, frequency, amplitude, and phase modulation. Frequency, amplitude, and phase modulation are commonly used in non-UWB (narrow-band) communication systems. Examples of such narrowband communication systems include broadcast AM, FM as well as those defined by IEEE 802.11 (a), (b) or (g), also know as wireless LAN (WLAN) applications. A robust and popular version of UWB modulation has been referred to as bi-phase modulation. This technique utilizes a broadband 180 phase-shift device to create mirror images of the waveform (pulse or wavelet). The inventors of the embodiments referenced herein sometimes refer to this form of modulation as “flip” modulation since it involves flipping, or inverting a waveform (pulse or wavelet).

The design and implementation of UWB systems and components requires the conveyance of these RF signals on unbalanced or balanced transmission lines. A balanced transmission line is a pair of lines that has electrical phase symmetry wherein the RF signal exists as the difference in potential between these paired current conducting paths. (Though most common, a balanced transmission line is not explicitly required to have amplitude or physical symmetry.) As such, an earth or null potential always exists somewhere between the physical centers of these two current paths. Whereas in an unbalanced line this neutral or null position is defined to be coincident with one of the current paths. One of the advantages of the balanced line is that an interfering magnetic field will not couple well to this structure, thus resulting in some noise immunity.

“Balun” is an abbreviation for balanced/unbalanced. It is associated with any device or structure used to convert a balanced line to an unbalanced line and vice versa. They are integral to the design of many antennas and are in common use in single, double and triple balanced mixers.

Conventional discrete baluns mostly comprise tightly coupled input/output structures fabricated with wires wrapped on ferrite materials, though they can be implemented with film deposition techniques in multiplayer ceramic substrates, or even with standard multiplayer printed circuit board fabrication technology. They can be based upon direct transformer type coupling or distributed transmission line coupling methods to achieve their function. A problem arises when these wire/ferrite and printed line techniques are extended to higher frequencies (˜>1 GHz) where UWB signals are most often employed. These structures of necessity become smaller and more difficult to precisely manufacture, and tend to develop excessive loss of signal, a loss in degree of balance, and electrical dispersion wherein different frequencies pass through the device with differing electrical delay. Baluns implemented utilizing wideband distributed microwave techniques in microstrip, stripline, slotline, or related line structures suffer these maladies to a lesser extent. However, distributed implementations can become increasingly problematic at lower frequencies (˜<1 GHz) because of the planar space they consume.

A prior art balun structure implemented using distributed transmission lines is known as the Marchand Balun. A recent analysis is disclosed in Kian Sen Ang, “Analysis and Design of Impedance-Transforming Planar Marchand Baluns”, IEEE Trans. Microwave Theory Tech., vol. 49, pp. 402, February 2001. The Marchand Balun is popular because of its ability to create a well balanced phase and amplitude output over a large bandwidth. On planar media, a Marchand balun is usually fabricated using a high dielectric constant material where the transmission lines are meandered to minimize size. In general, the Marchand balun comprises two pairs of quarter wave transmission lines, with one of the pairs being coupled lines comprising either shorted or open stub terminations. A stub is an isolated section of a transmission line having on one end either an open or shorted termination and is joined to the main transmission at the other end.

FIG. 1 shows a prior art Marchand balun 100 implemented with open stub termination. A first pair of quarter wave coupled lines 102 performs the coupling from an unbalance input port 104 to one of the balanced output ports 106. The other balanced output port 108 is coupled to a second pair of quarter wave coupled lines 110, which comprises the open stub termination. The open stub termination 112 balances the over-all structure. The balanced output is provided by the potential difference between the ports 106 and 108. FIG. 2 shows another prior art Marchand balun 200 implemented with a short stub termination 202.

Baluns can be integrated into a Radio Frequency Integrated Circuit (RFIC). For example, Hittite Microwave Corporation offers a GaAs MMIC bi-phase modulator/demodulator that covers 1.8-5.2 GHz. This bi-phase modulator uses the Marchand balun to divide an RF signal into reference and 180 degree states.

Baluns suitable for UWB service are not only required to create a balanced set of outputs at all the frequencies occupied by the UWB signal, but also propagate those signals through the balun with equal electrical delay at all of those frequencies. A device not having this equal delay property is said to be dispersive. Stub transmission lines are known to introduce dispersion (phase delay) and this characteristic of the Marchand balun represents its primary failing for UWB.

Gupta et al., K C, Microstrip Lines and Slotline Artech house, 1979, disclose a prior art balun circuit 300 shown in FIG. 3 that produces a 180 degree phase shift to an input waveform. As shown in FIG. 3, balun circuit 300 includes a first microstrip 302 having ground 303 and unbalanced input 304, and a second microstrip 306 having ground 307 unbalanced output 308. The first microstrip 302 and second microstrip 306 are connected by slotline 310 having first slot line open circuit 312 and second slot line open circuit 314 to produce back-to-back microstrip to slotline transitions that introduce the 180 degree phase shift into the signal path. As disclosed, the prior art balun circuit 300 has one input 304 and one output 308 where the output waveform is an inverted version of the input waveform.

Because of their ultra-wide bandwidth, special considerations also apply to bi-phase modulation of UWB signals. One prior art bi-phase modulator is disclosed in PCT International Publication No. WO 01/93520 A2. Designs such as this, when based upon classic mixer structures utilized as a switchable crossover transformer, may suffer some of the maladies described earlier.

Other prior art approaches for bi-phase modulation of UWB signals utilize separate wavelet generators, with one structure generating a non-inverted wavelet or pulse and the other generating an inverted wavelet or pulse. A selection network selects the desired output of one of the wavelet generators. One such bi-phase modulator is used in a UWB communication system disclosed in US Patent Application Publication No. US/2003/0053555. The disclosed system uses a positive wavelet generator and a negative wavelet generator to generate wavelets of opposite polarity. A switch coupled to the outputs of the positive wavelet generator and negative wavelet generator selectively provides a positive (non-inverted) or negative (inverted) wavelet. Because both of the wavelet generators must be turned on during data transmission, this form of UWB bi-phase generation suffers a power consumption penalty.

Another prior art approach selectively enables either a positive wavelet generator or a negative wavelet generator based on an information signal, where the wavelet generator not selected to be enabled is instead disabled. However, this approach suffers from the need for very careful matching of the timing performance of the two independent circuits.

Therefore, there remains a need for a low DC power and elegant UWB bi-phase modulator that generates accurately matched antipodal waveforms of opposite polarity with maximally flat phase delay over the bandwidth of an UWB signal.

### SUMMARY OF THE INVENTION

One of the features of the present invention is a bi-phase modulator that modulates UWB signals without requiring two separate wavelet generators. Briefly, according to the present invention, the bi-phase modulator includes a symmetrical transformation device and a selector device. The symmetrical transformation device accepts an input UWB waveform that is output by a UWB waveform generator, for example a pulse or a wavelet, and simultaneously creates two output waveforms that are inverted and non-inverted versions of the input UWB waveform. Except for opposite polarity, both output UWB waveforms are required to be substantially identical, which the present invention achieves to a very high degree. The selector device then presents either the non-inverted or the inverted UWB waveforms to the output port, or to another balun for full conversion of the available waveform energy to a common unbalanced output port. The selector device operates in response to the state of an information signal representing the modulation source. The information signal can be one or a combination of a data and a channelization signal.

According to some of the more detailed features of the present invention, the electrically symmetrical structure of the symmetrical transformation device promotes excellent broadband phase and amplitude balance, and the absence of “stub” structures on the serially coupled input and output transmission lines substantially control phase delay dispersion across the bandwidth of the UWB signal. The transmission lines used in the present invention can be any one of several coupled line structures such as coaxial lines, slotlines, microstrips, and striplines, among others. The transmission lines are often tapered to provide impedance matching between the generator and load, or for other purposes such as reducing peak voltage swings on selecting (switching) devices in higher-power applications.

In one embodiment, the symmetrical transformation device includes a first input transmission line, for example a microstrip, coupled to a second balanced transmission line, for example a slotline, which in turn symmetrically couples to a third transmission line, for example a microstrip, having two unbalanced outputs. In a preferred embodiment, a first input transmission line, for example a microstrip, transitions to a second balanced transmission line, for example a slotline, and associated with the transition is a slotline open circuit. Associated with the second balanced transmission line transition to the third unbalanced transmission line is an additional slotline open circuit.

In one exemplary embodiment, a pair of output unbalanced transmission lines convey mirror image copies of the structure's unbalanced input waveform (pulse or wavelet) to an unbalanced selector device for conveyance of the desired waveform to the output. In another exemplary embodiment, the selector comprises a balanced crossover switch that serially conveys the equal and opposite waveforms (pulse or wavelet) from a balanced set of input transmission lines (resulting from a balun on the input side of this modulator) to a balanced set of output transmission lines, wherein another balun structure converts these signals to an unbalanced output. In all cases the selector is under control of the information source to be modulated onto the passing waveform (pulse or wavelet).

According to other more detailed features of the present invention, a discrete symmetrical transformer comprises a center-tapped transformer having a primary winding for receiving the input wavelet energy and a secondary winding that provides output waveform (pulse or wavelet) energy to a differentially fed UWB antenna.

### BRIEF DESCRIPTION OF THE DRAWINGS

FIG. 1 is a diagram of a prior art Marchand balun having an open stub.

FIG. 2 is a diagram of a prior art Marchand balun having a closed stub.

FIG. 3 is a diagram of a prior art balun having serially coupled transmission lines.

FIG. 4 depicts a symmetrical transformation device in accordance with one embodiment of the present invention.

FIG. 5 is another symmetrical transformation device in accordance with a preferred embodiment of the invention.

FIG. 6 depicts the overlaying of structure layers of the symmetrical transformation device of FIG. 5.

FIG. 7 is a block diagram of a bi-phase modulator in accordance with one embodiment of the present invention.

FIG. 8 is a diagram of a bi-phase modulator in accordance with another embodiment of the present invention.

FIG. 9 is a diagram of a bi-phase modulator in accordance with yet another embodiment of the present invention.

FIG. 10 is a diagram of a bi-phase modulator in accordance with yet another embodiment of the present invention.

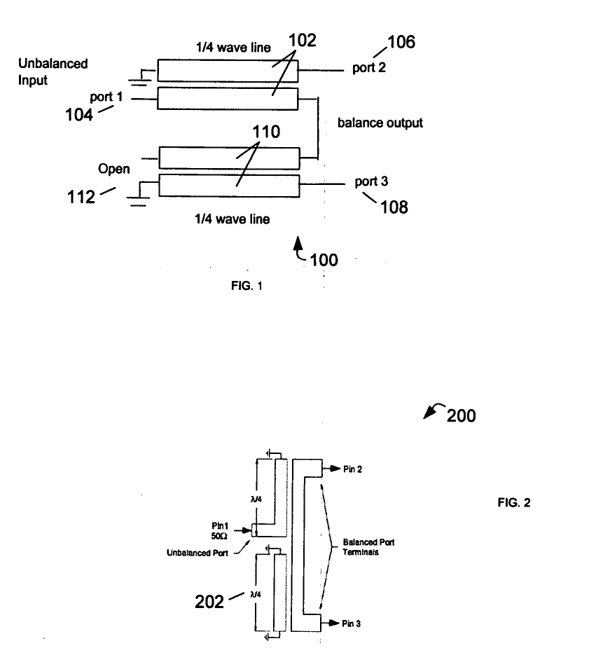

### DETAILED DESCRIPTION OF THE INVENTION

The bi-phase modulator of the present invention is used for modulating UWB signals in response to the state of an information signal. As herein defined, a UWB signal comprises any signal having relative bandwidth greater than or equal to 10% or defined as a UWB signal by communication rules and/or regulations of a governmental agency, for example, Federal Communications Commission (FCC) rules governing Part 15 signal emissions. UWB signals include, but are not limited to PPM, frequency, phase (e.g., flip) and amplitude modulated (or a combination thereof) signals that have an ultra-wide bandwidth. An information signal used for modulating the UWB signals according to the present invention comprises at least one of a data signal and a channelization signal. A data signal can correspond to binary data bits communicated over a communication channel. A channelization signal defines a communication channel, for example, a time hopping code. In one simple implementation, the bi-phase modulator of the present invention can provide inverted or non-inverted pulses (or any other type of wavelet) based on the binary state of bits of an information signal producing by multiplying a channelization signal by a data signal.

The bi-phase modulator of the present invention accepts as input a sequence of suitable waveforms (pulse or wavelet) for a desired UWB application, including but not limited to any of data communication, radar, positioning; locating or tracking applications. Examples of such waveforms include but are not limited to any of gaussian pulses and their derivatives, impulse responses of standard filters, or any of application specific chirp or frequency/phase dispersed waveforms which meet the bandwidth and/or regulatory requirements of UWB. One exemplary wavelet generator used in the bi-phase modulator of the present invention is disclosed in U.S. patent application Ser. No. 09/537,692, which is incorporated herein by reference.

The bi-phase modulator of the present invention also includes a symmetrical transformation device. A symmetrical transformation device as defined herein includes any structure that allows for conversion of its input waveform energy into two substantially identical equal energy first and second output wavelets of opposite polarity. In other words, the symmetrical transformation device converts the input waveform into a pair of duplicate output waveforms (pulses or wavelets) having mirror image opposite symmetry. The duplicate yet opposite polarity output waveforms may or may not be replicas of the input waveform. The bi-phase modulator also includes a selector, e.g., a switch, which selects one of the first or second output waveforms in response to the state of the information signal.

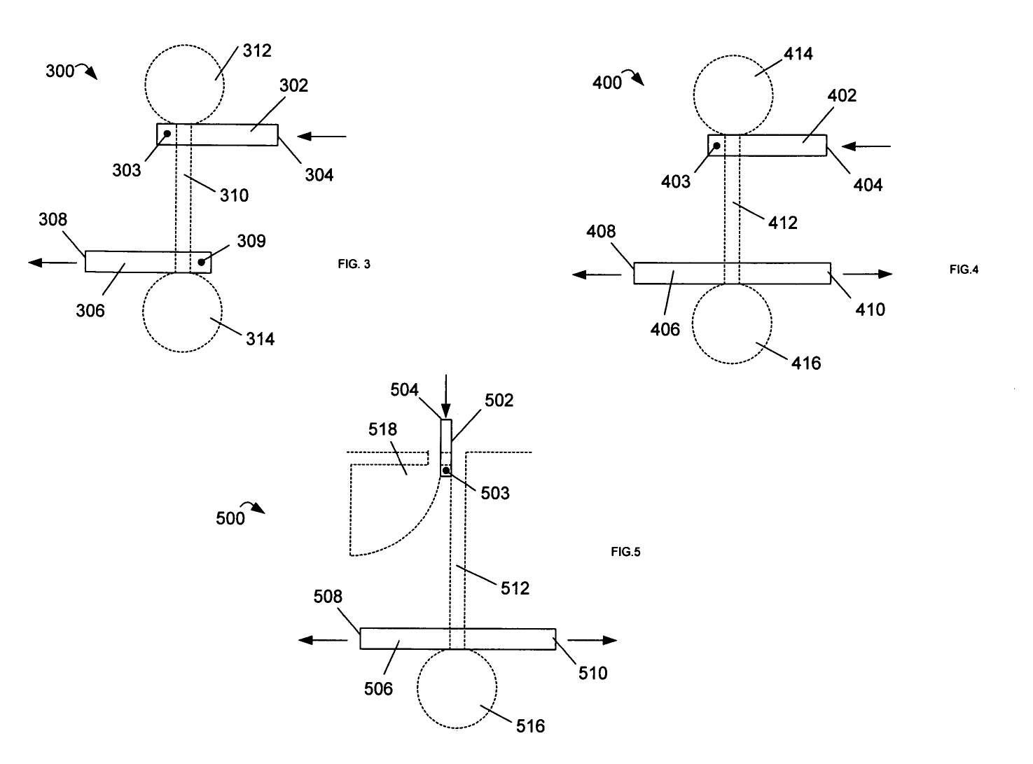

One embodiment of the symmetrical transformation device of the present invention is produced by modifying the balun circuit 300 of FIG. 3 to have two unbalanced outputs having equal but opposite polarity versions of an input waveform as depicted in FIG. 4. Referring to FIG. 4, symmetrical transformation device circuit 400 includes a first microstrip 402 having ground 403 and unbalanced input 404, and a second microstrip 406 having unbalanced output 408 and unbalanced output 410. The first microstrip 402 is unbalanced and encounters slotline 412 where it propagates to second microstrip 406 in a balanced mode. At the junction of slotline 412 and second microstrip 406 a set of substantially identical contra-propagating waveforms of opposite polarity are created and propagate to unbalanced outputs 408 and 410. As disclosed, the symmetrical transformation device circuit 400 has one input 404 and two outputs 408, 410 where one output waveform is an inverted version of the input waveform and the other output waveform is a non-inverted version of the input waveform.

FIG. 5 presents a preferred embodiment of the invention that is similar to FIG. 4. In FIG. 5, symmetrical transformation device circuit 500 includes a first microstrip 502 having ground 503 and unbalanced input 504 that in conjunction with open slot line circuit 518 converts unbalanced energy on microstrip 502 to balanced energy on slotline 512 where it propagates to second microstrip 506 in a balanced mode. At the junction of slotline 512 and second microstrip 506 a set of substantially identical contra-propagating waveforms of opposite polarity are created and propagate to unbalanced outputs 508 and 510. As disclosed, the symmetrical transformation device circuit 500 has one input 504 and two outputs 508, 510 where one output waveform is an inverted version of the input waveform and the other output waveform is a non-inverted version of the input waveform.

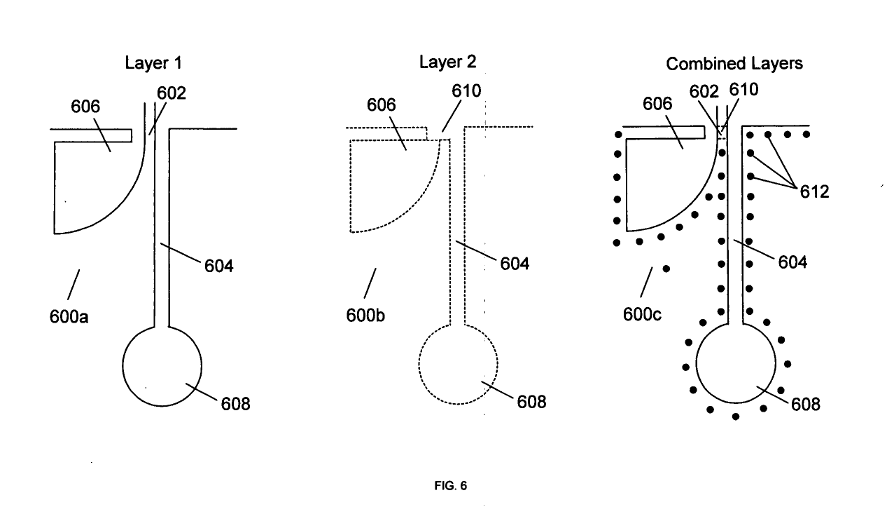

FIG. 6 depicts substrate structure layering of the preferred embodiment of the transition from a first unbalanced microstrip transmission line to a balanced slotline transmission line within the symmetrical transformation device of FIG. 5. Not shown for clarity is the third microstrip transmission line referenced elsewhere which conveys the outputs. Referring to FIG. 6, Layer 1 (600a) of the structure includes an input microstrip transmission line 602 that conveys an input waveform to a transition region including a slotline 604a and slotline open circuit 606a. The input waveform is hence conveyed in balanced mode to slotline open circuit 608a where it is symmetrically coupled to an output unbalanced microstrip transmission line (not shown). Promoting the achievement of practical low impedance slotline processing, better bandwidth, better balance and better return loss is the addition of Layer 2 (600b) immediately below Layer 1 (600a) with an interstitial substrate layer. Layer 2 (600b) is similar to Layer 1 (600a) except slotline 604b, which overlays slotline 604a, is extended to include additional slotline region 610 to connect slotline 604b to slotline open circuit 606b, where slotline 604a overlays slotline 604b and slotline open circuits 606a and 608a overlay slotline open circuits 606b and 608b. Layer 1 (600a) and Layer 2 (600b) are shown as Combined Layers (600c) with necessary connectivity of equi-potential surfaces between Layer 1 (600a) and Layer 2 (600b) promoted by the numerous via holes 612 and including combined slotline layers 604 and combined slotline open circuits 606, 608.

A problem addressed in the preferred embodiment is the utilization of balanced slotline transmission lines of standard working value impedances, for example 50 ohms. The preferred embodiment utilizes minimum impedance deviations from 50 ohms to promote maximum bandwidth and minimum dispersion and loss. Classic slotline transmission lines require very small and precise gap dimensions for low impedances, which make the processing of low impedance lines impractical on many common substrates. This was resolved by the addition of the second balanced slotline structure (604a,606a, and 608a) overlaid with the first balanced slotline structure (604b, 606b, and 608b) as shown in FIG. 6. This approach has two benefits. First, it allows an increase in each slotine gap dimension and hence promotes a relative reduction in precision processing need for realizing low impedances. Second, the transition from microstrip transmission line to balanced slotline transmission line is accomplished with better balance on the slotline and better return loss at the microstrip input than would otherwise occur.

In one embodiment, the energy transformation according to the present invention comprises dividing the energy of the input waveform (pulse or wavelet) into two equally energized first and second output waveforms of opposite polarity. Under this arrangement, the output waveforms are not necessarily replicas of the input waveform although they may resemble the input waveform type, shape, or energy. The intent is that the two output waveforms have substantially strong symmetry.

In an alternative embodiment, the energy transformation can include converting the energy of the input wavelets to the energy of output wavelets either directly or inversely, based on the state of the information signal. This embodiment, which can be implemented by any suitable balanced crossover switching arrangement, presents two output waveforms having substantially the same energy as the input waveform, albeit with opposite polarities as controlled by the state of the information signal. Under this arrangement, the output waveforms are not necessarily replicas of the input although they may resemble the input waveform type, shape, or energy. Again, the intent is that the two output waveforms have substantially strong symmetry.

The symmetrical transformation device can be implemented using discrete, lumped and/or distributed components and structures. As such, the structure of the symmetrical transformation device typically comprises transmission lines implemented in coax, waveguide, stripline, microstrip, windings, slotline, and any of their variants, as well as with any lumped element equivalent transmission line or transformation circuits, and in uncoupled or coupled variants as may suit design attributes and purpose.

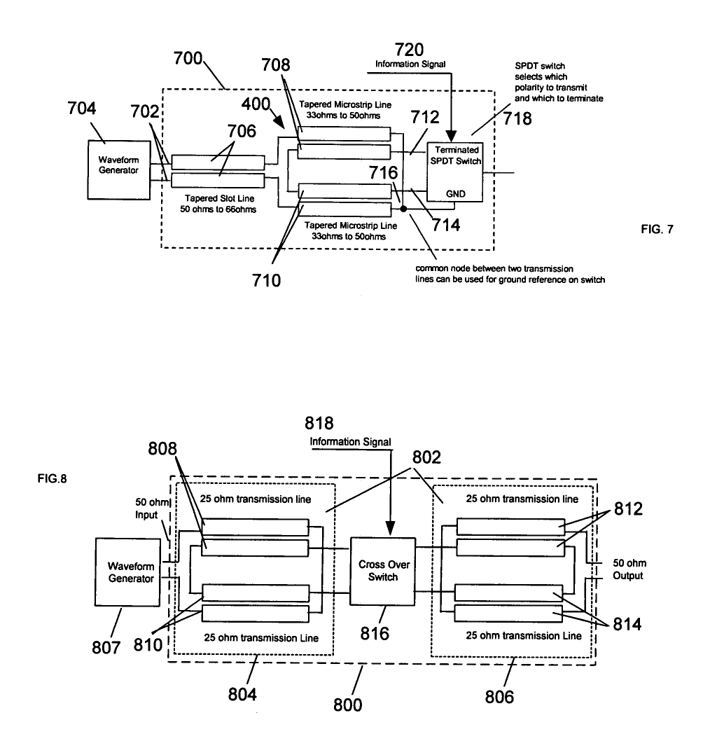

FIG. 7 shows the diagram of a bi-phase modulator 700 that uses the symmetrical transformation device circuit 400 of FIG. 4 for modulating UWB signals according to the present invention. The bi-phase modulator 700 receives balanced input 702 from balanced waveform generator 704 and applies balanced input waveforms to input transmission lines 706. Optionally, an unbalanced waveform generator and a balun can be used to apply balanced input waveforms to input transmission lines 706. The input transmission lines 706 are serially coupled to first output transmission lines 708 and second output transmission lines 710, having corresponding output ports 712 and 714. As shown, the output ports 712 and 714 have a common node 716, which is considered a virtual ground and coupled to ground. As such, first and second output transmission lines 708 and 710 provide corresponding first and second unbalanced outputs 712 and 714 representing opposite polarity waveforms.

A switch 718 selects one of the first and second unbalanced outputs 712 and 714 in response to a control signal that represents or otherwise corresponds to the state of the information signal 720. In a preferred embodiment, the switch 718 is a terminating single-pole-double-throw (SPDT) RF switch that is grounded by the common node 716. Terminate in this sense is the process of placing a load on a transmission line such that no reflection is created, i.e., to convert the unwanted signal energy into heat. Consequently, in response to the state of the information signal, one of the unbalanced outputs is selected, while the other unbalanced output disappears completely.

The embodiment shown in FIG. 7 can be characterized as having the waveform generator 704 coupled to the balanced port of the symmetrical transformation device circuit 400, while the switch 718 is used to present a selected output wavelet energy at one of the two unbalanced outputs 712 and 714. This embodiment of the invention provides a mechanism to selectively invert or not-invert the input wavelet in response to the state of the information signal.

Preferably, the input and output transmission lines 706, 708, and 710 are properly matched to avoid RF reflections and provide optimal bandwidth behavior. For example, the input transmission lines 706 can be tapered from 50 ohms to 66 ohms and the first and second output transmission lines 708 and 710 can each be tapered from 33 ohms to 50 ohms utilizing linear, exponential, Kopfenstein or Hecken tapers. As such the series connection between the input transmission lines 706 and output transmission lines 708 and 710 results in 50 ohm impedance at the input and output ports of the symmetrical transformation device. Under this embodiment, the first input transmission lines 706 and the first and second output transmission lines 708, 710 comprise corresponding tapered coupled lines for providing the impedance matching at the input port 702 and the first and second output ports 712, 714.

FIG. 8 shows yet another embodiment of the bi-phase modulator 800 of the present invention. As in FIG. 7, the balanced waveform generator can be replaced by an unbalanced waveform generator and a balun. According to this embodiment, there are two symmetrical transformation devices 802 comprising a primary side 804 and a secondary side 806. More specifically, the bi-phase modulator 800 applies input waveforms from the waveform generator 807 to first and second serially coupled input transmission lines 808 and 810, which are disposed on the primary side 804. The output waveforms are provided by first and second serially coupled output transmission lines 812 and 814, which are disposed on the secondary side 806. A balanced crossover switch 816 acts to transfer the energy from the primary side 804 to the secondary side 806 in response to the state of the information signal 818. Under this embodiment, the switch 816, which is controlled by the information signal 818, has two switching states: a direct connection state and an inverted connection state. In the direct connection state, the balanced crossover switch 816 transfers the input wavelet energy applied at its balanced input ports directly to its balanced output ports without a crossover of the signal energy to the balanced structure it feeds. In the inverted connection state, however, the balanced crossover switch 816 imparts a crossed over connectivity from the input waveform energy applied at its balanced input ports to its balanced output ports. In the preferred embodiment the balanced crossover switch 816 is fabricated using GaAs FET technology as the most cost-effective solution embodied in generic commercial devices, though PIN diode devices can be readily utilized to implement higher power capability.

The embodiment shown in FIG. 8 can be characterized as having a back-to-back balun structure, i.e., one on the primary side and the other on the secondary side, and a crossover switch in between that converts the input waveform energy into output waveform energy either directly or inversely. Consequently, this embodiment eliminates the losses associated with terminating an unselected output port at ground such as embodied in FIG. 7.

Preferably, the bi-phase modulator 800 uses geometrically symmetrical transmission lines for energy transformation from the primary side to the secondary side, thereby obviating the need for impedance matching between the two sides. For example, the first and second serially coupled input transmission lines 808 and 810 can each have 25 ohms impedance to present a 50 ohms impedance at the input of the symmetrical transformation device 802. Similarly, the first and second serially coupled output transmission lines 812 and 814 can each have 25 ohms impedance to present a 50 ohms impedance at the output of the symmetrical transformation device 802. It would be appreciated that because of the geometrical symmetry of the structure of FIG. 8, a positive polarity wavelet follows a similar path to a negative polarity wavelet. Thus, the symmetrical transformation device 802 can be manufactured with very repeatable balance characteristics between a positive polarity waveform and a negative polarity waveform, a desirable attribute of UWB bi-phase modulators.

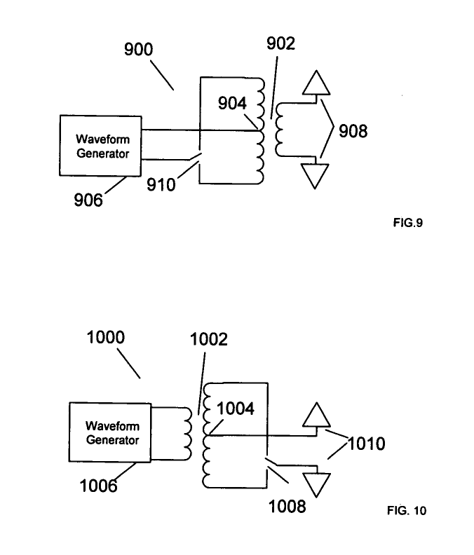

FIGS. 9 and 10 disclose two more embodiments of bi-phase modulators of the present invention. Both embodiments use center tapped transformers for transforming the input waveform energy to output waveform energy in accordance with the present invention.

In FIG. 9, the bi-phase modulator 900 consists of a symmetrical transformation device 902 that has a primary center tap 904 coupled to a waveform generator 906 that produces input waveform energy. In response to the information signal, which controls primary switch 910, the secondary coupling mechanism of the symmetrical transformation device 902 presents a direct or inverted output waveform energy to a differential UWB antenna 908 as shown.

In FIG. 10, the bi-phase modulator 1000 uses a symmetrical transformation device 1002 having a secondary center tap 1004 at the secondary coupling mechanism. A waveform generator 1006 coupled to the primary coupling mechanism of the symmetrical transformation device 1002 generates input waveform energy. In response to the information signal, which controls secondary switch 1008, the center tapped secondary coupling mechanism presents a direct or inverted out put waveform energy to a differential UWB antenna 1010.

It would be appreciated that the various embodiments of the bi-phase modulator of the present invention can be implemented using various types of simple symmetrical transformation devices that obviate the need for complex matched circuitry of positive and negative waveform generators of prior art. Also, the bi-phase modulator of the present invention can comprise serially coupled transmission lines, without any dispersive elements. Therefore, the bi-phase modulator provides minimal distortion over the bandwidth of the bi-phase modulated UWB signal.

1. A bi-phase modulator for an ultra wideband signal, comprising:
a symmetrical transformation device that receives an input UWB waveform and converts the energy of the input waveform into the energy of a first waveform and a second waveform, wherein the first waveform and second waveform are substantially identical waveforms of opposite polarity; and
a selector device that presents one of the first waveform and second waveform at the output of the bi-phase modulator in response to the state of an information signal and concurrently terminates the other one of the first waveform and second waveform.

2. A bi-phase modulator for an ultra wideband signal, comprising:
a first symmetrical transformation device that receives an input waveform and converts the energy of the input waveform into the energy of a first waveform and a second waveform, wherein the first waveform and output waveform are substantially identical waveforms of opposite polarity;
a second symmetrical transformation device that receives the first waveform and the second waveform and converts the energy of the first waveform and the second waveform into the energy of an output waveform; and
a selector device serving as a crossover switch between the first symmetrical transformation device and the second symmetrical transformation device which presents the first waveform and the second waveform via a direct connection state or and inverted connection state in response to the state of an information signal.

3. The bi-phase modulators of claims 1 and 2, wherein the symmetrical transformation device comprises balanced transmission lines serially coupled to unbalanced transmission lines.

4. The bi-phase modulator of claim 3, wherein the selector comprises a switch having a ground reference connection to one of a virtual ground and a physical ground associated with one of the balanced transmission lines and the unbalanced transmission lines.

5. The bi-phase modulator of claim 3, wherein at least one of the balanced transmission lines and unbalanced transmission lines has impedance tapers.

6. The bi-phase modulator of claim 1, wherein the symmetrical transformation device comprises a center tapped primary transformation device having a primary to secondary field coupling mechanism for selective waveform polarity conveyance to a differential device.

7. The bi-phase modulator of claim 6, wherein said differential device is a UWB antenna.

8. The bi-phase modulator of claim 1, wherein the symmetrical transformation device comprises a center tapped secondary transformation device having a primary to secondary field coupling mechanism for selective waveform polarity conveyance waveform coupling mechanism to a differential device.

9. The bi-phase modulator of claim 1, wherein the symmetrical transformation device comprises a center tapped primary transformation device having a primary to secondary field coupling mechanism for selective waveform polarity conveyance to a differential device.

10. The bi-phase modulator of claim 9, wherein said differential device is a UWB antenna.

11. The bi-phase modulator of claim 2, wherein at least one of the first symmetrical transformation device and the second symmetrical transformation device comprises a center tapped primary transformation device having a primary to secondary field coupling mechanism for selective waveform polarity conveyance to a differential device.

12. The bi-phase modulator of claim 11, wherein said differential device is a UWB antenna.

13. The bi-phase modulator of claim 2, wherein at least one of the first symmetrical transformation device and the second symmetrical transformation device comprises a center tapped secondary transformation device having a primary to secondary field coupling mechanism for selective waveform polarity conveyance waveform coupling mechanism to a differential device.

13. The bi-phase modulator of claim 13, wherein said differential device is a UWB antenna.

14. The bi-phase modulator of claims 1 and 2, wherein the information signal comprises at least one of a data signal and a channel signal.

16. The bi-phase modulator of claim 13, wherein the channel signal is in accordance with a time hopping code.

17. A bi-phase modulator for an ultra wideband (UWB) signal, comprising:
a symmetrical transformation device that receives an input UWB waveform and converts the energy of the input UWB waveform into the energy of a first output UWB waveform and a second output UWB waveform, wherein the first output UWB waveform and second output UWB waveform are substantially identical waveforms of opposite polarity; and
a selector that presents one of the first output UWB waveform and second output UWB waveform at the output of the bi-phase modulator in response to the state of an information signal.

18. The bi-phase modulator of claim 17, wherein the symmetrical transformation device comprises input transmission lines that are serially coupled to output transmission lines.

19. The bi-phase modulator of claim 18, wherein the output transmission lines have a common node.

20. The bi-phase modulator of claim 19, wherein the selector comprises a switch that is grounded by the common node.

21. The bi-phase modulator of claim 18, wherein at least one of the input transmission lines and output transmission lines comprise at least one of coupled lines, coaxial lines, slotlines, microstrips, and striplines.

22. The bi-phase modulator of claim 18, wherein the input and output transmission lines are tapered transmission lines.

23. The bi-phase modulator of claim 18, wherein the selector comprises a crossover switch that serially couples the input transmission lines to the output transmission lines, said crossover switch being responsive to the state of the information signal for presenting one of the first output UWB waveform and second output UWB waveform at the output of the bi-phase modulator.

24. The bi-phase modulator of claim 17, wherein the symmetrical transformation device divides the energy of the input waveform into energies of the first output UWB waveform and second output UWB waveform.

25. The bi-phase modulator of claim 17, wherein the symmetrical transformation device converts the energy of the input waveform into the energy directly into the first output UWB waveform or inversely into the second output UWB waveform based on the state of the information signal.

26. The bi-phase modulator of claim 25, wherein the symmetrical transformation device uses a crossover switching arrangement for direct or inverse transformation of the energy of the input waveform into the energy of one of the first output UWB waveform and second output UWB waveform.

27. The bi-phase modulator of claim 17, wherein the symmetric transformation device comprises a center tapped transformation device having a primary coupling mechanism for receiving the input UWB waveform and a secondary coupling mechanism coupled to a differential UWB antenna.

28. The bi-phase modulator of claim 17, wherein the symmetric transformer comprises a center tapped transformation device having a secondary coupling mechanism for receiving the input UWB waveform and a primary coupling mechanism coupled to a differential UWB antenna.

29. The bi-phase modulator of claim 17, wherein the information signal comprises at least one of a data signal and a channel signal.

30. The bi-phase modulator of claim 29, wherein the channel signal is in accordance with a time hopping code.

31. A symmetrical transformation device, comprising:
a first input transmission line having an unbalanced input for receiving an input UWB waveform;
a second transmission line, said second transmission line being balanced and being coupled to said first transmission line; and
a third transmission line, said third transmission line having a first unbalanced output and a second unbalanced output and being coupled to said second transmission line;
wherein a first output UWB waveform is output the first unbalanced output and a second output UWB waveform is output the second unbalanced output, wherein said first output UWB waveform and said second output UWB waveform are substantially identical but have opposite polarity.

32. A bi-phase modulator for an ultra wideband signal, comprising:
a symmetrical transformation device that receives an input UWB waveform and converts the energy of the input waveform into the energy of a first output waveform and a second output waveform, wherein the first output waveform and second output waveform are substantially identical waveforms of opposite polarity; and
a selector device that determines based on an information signal which one of the first output waveform and second output waveform are presented at the output of the bi-phase modulator.
